(19) United States
(12) Patent Application Publication
(10) Pub. No.: US 2021/0191400 A1
(43) Pub. Date: Jun. 24, 2021

(54) AUTONOMOUS VESSEL SIMULATION SYSTEM AND OPERATING METHOD THEREOF

(71) Applicant: Ship and Ocean Industries R&D Center, New Taipei City (TW)

(72) Inventors: FENG-YEANG CHUNG, New Taipei City (TW); CHUN-HAN CHU, New Taipei City (TW); CHIA-CHUAN OU, New Taipei City (TW); MING-HSIANG HSU, New Taipei City (TW); CHUN-JUNG CHEN, New Taipei City (TW); CHI-MIN LIAO, New Taipei City (TW); YING-CHAO LIAO, New Taipei City (TW)

(21) Appl. No.: 17/112,979

(22) Filed: Dec. 4, 2020

(30) Foreign Application Priority Data
Dec. 20, 2019 (TW) 108146817

(51) Int. Cl. G05D 1/02; G08G 3/02

(52) U.S. Cl. CPC G05D 1/0206; G08G 3/02

(57) ABSTRACT

The present invention discloses an autonomous vessel simulation system, comprising an environment model building system, a vessel model building system and a central processing system. The environment model building system builds at least one environment model; the vessel model building system builds at least one vessel model and an operation module of the central processing system integrates the environment model and the vessel model. The vessel model is navigated in the environment model according to at least one navigational parameter, and a display module displays the navigation status of the vessel model. In addition, an operating method of the autonomous vessel simulation system is also provided.

### TECHNICAL FIELD

The present invention relates to a kind of autonomous vessel simulation system and operating method thereof. Specifically, the autonomous vessel simulation system is used to build an environment model and a vessel model together for integration.

### BACKGROUND OF RELATED ARTS

With the development of science and technology, accompanying with the increasing number of ships and traffic volume, ship navigation safety and energy saving have become a major issue. With the developing technologies such as integrated bridge systems (IBS) and automatic navigation systems, the autonomous surface vehicle (ASV) can effectively reduce labor costs, reduce the probability of ship accidents, and improve ship operation efficiency.

Autonomous navigation specifically refers to the fact that after obtaining the destination of the ship, the ship can autonomously perceive information about the surrounding environment, independently design the navigation, and independently control the ship without human participation. Following the initial voyage process, the process of autonomous navigation involves complicated data processing, integration, optimization, and artificial intelligence. At present, the relevant theories and methods are not perfect enough, and further research is urgently needed. However, research on theories and technologies related to autonomous navigation requires high costs, and the lack of understanding of ships or other uncertain factors may lead to experimental failures and even dangers during the process of experimental verification.

With the development of computing devices and simulation technology, simulation experiments have become a necessary research method before real experiments.

### SUMMARY

In order to solve the problems of the prior arts, the present invention provides an autonomous vessel simulation system, comprising: an environment model building system, a vessel model building system and a central processing system.

The environment model building system builds at least one environment model. The environment model building system comprises: an environment information collecting system, collecting at least one piece of environment information in a real environment. An environment information database is connected with the environment information collecting system, and an electronic chart information in the real environment and the at least one piece of environment information in the real environment are stored in the environment information database. An environment model building module is connected with the environment information collecting system and the environment information database, and the environment model building module is configured to integrate the at least one piece of environment information with the electronic chart information, building at least one environment model.

The vessel model building system builds at least one vessel model. The aforementioned vessel model building system comprises: a vessel parameter setting module. Furthermore, at least one dynamic parameter and at least one static parameter of the at least one vessel are set by the vessel parameter setting module, and a vessel information database is connected with the vessel parameter setting module. The at least one dynamic parameter and the at least one static parameter are stored in the vessel information database. A vessel model building module is connected with the vessel parameter setting module and the vessel information database, and the vessel model building module is configured to integrate the at least one dynamic parameter with the at least one static parameter, building the at least one vessel model.

The central processing system connects with the environment model building system and the vessel model building system, and the central processing system comprises: a navigational parameter setting module which is used to set at least one navigational parameter. An operation module is connected with the navigational parameter setting module, and the operation module is configured to integrate the at least one environment model with the at least one vessel model, allowing the at least one vessel model to be navigated through the at least one environment model with the at least one navigational parameter. A display module of this invention is connected with the operation module, and the at least one environment model and the at least one vessel model are displayed on the display module.

Furthermore, the present invention provides a method of using an autonomous vessel simulation system, the steps comprise: (A) provide the autonomous vessel simulation system. (B) an environment model building system builds at least one environment model. (C) a vessel model building system builds at least one vessel model. (D) an operation module of a central processing system integrates the at least one environment model with the at least one vessel model. (E) a display module shows the at least one environment model and the at least one vessel model, and (F) the operation module allows the at least one vessel model to be navigated through the at least one environment model using the at least one navigational parameter set by a navigational parameter setting module.

Embodiments of the invention are illustrated by way of example, and not by way of limitation, in the figures of the accompanying drawings in which like reference numerals refer to similar elements.

### BRIEF DESCRIPTION OF THE DRAWINGS

FIG. 1 shows a schematic diagram of the autonomous vessel simulation system of the preferred embodiment of the present invention.

FIG. 2 shows a flow chart of the method of using the autonomous vessel simulation system of the preferred embodiment of the present invention.

### DETAILED DESCRIPTION OF THE INVENTION

In order to understand the technical features and practical efficacy of the present invention and to implement it in accordance with the contents of the specification, hereinafter, preferred embodiments of the present invention will be described in detail with reference to the accompanying drawings.

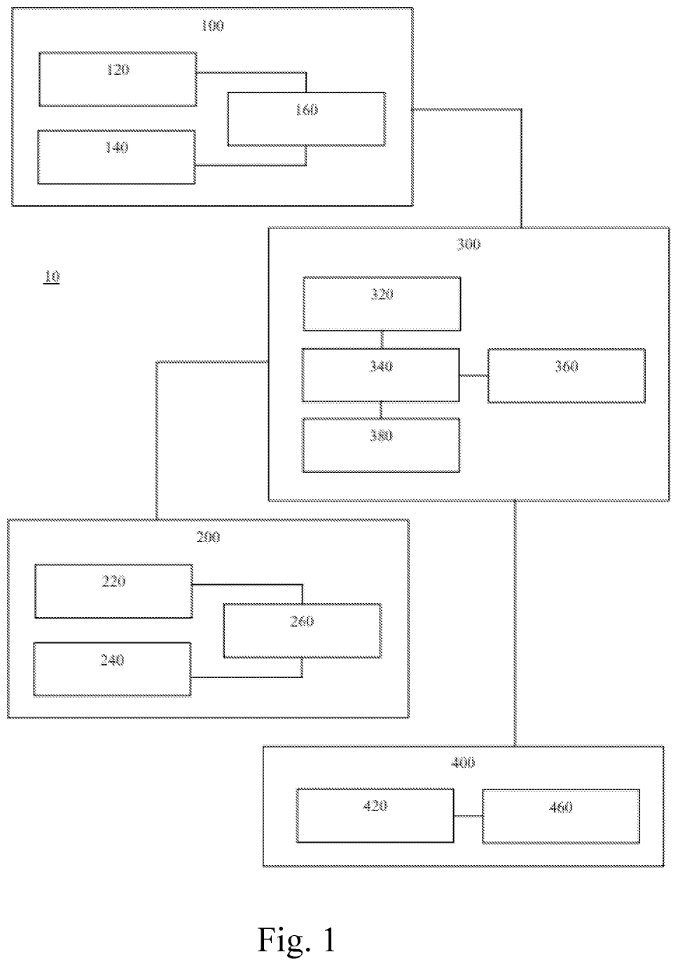

Please refer to FIG. 1. FIG. 1 is a schematic diagram of the autonomous vessel simulation system of the preferred embodiment of the present invention. As shown in FIG. 1, the substrate carrier latching structure 10 provided in the embodiment mainly comprises three systems: an environment model building system 100, a vessel model building system 200 and a central processing system 300.

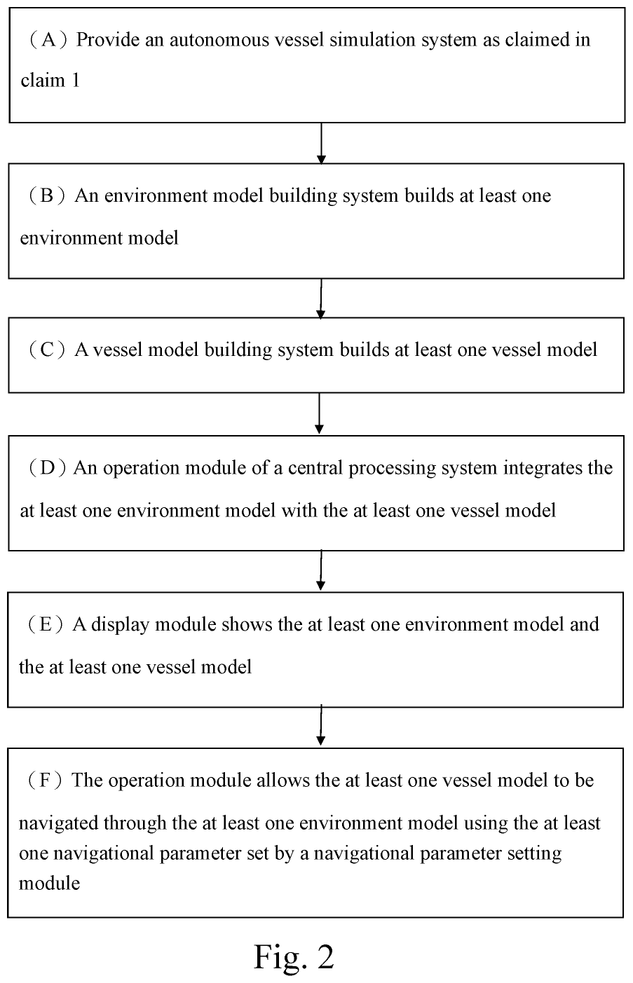

Please further refer to FIG. 2, it is a flow chart of the method of using the autonomous vessel simulation system of the preferred embodiment of the present invention. As shown in FIG. 2, the method of using an autonomous vessel simulation system comprising the following steps: (A) provide the autonomous vessel simulation system; (B) an environment model building system builds at least one environment model; (C) a vessel model building system builds at least one vessel model; (D) an operation module of a central processing system integrates the at least one environment model with the at least one vessel model; (E) a display module shows the at least one environment model and the at least one vessel model; and (F) the operation module allows the at least one vessel model to be navigated through the at least one environment model using the at least one navigational parameter set by a navigational parameter setting module.

Further, in step (B), the environment model building system integrates at least one piece of environment information with electronic chart information to build the at least one environment model. In step (C), the vessel model building system integrates at least one dynamic parameter with at least one static parameter of at least one vessel to build the at least one vessel model. In step (F), the operation module further allows the at least one vessel model to be navigated through the at least one environment model using at least one external navigational parameter set by an external navigational parameter setting module. In step (F), the at least one navigational parameter and the at least one external navigational parameter comprising departure point and destination point, route, obstacle site, tracking target or the combination thereof. Additionally, after step (E), a control module is used in an alternative step (f) to allow the at least one vessel model to be navigated through the at least one environment model.

In the embodiment, the purpose of the environment model building system 100 is to build an environment model to provide a virtual environment for testing. The environment model building system 100 comprises: an environment information collecting system 120, collecting at least one piece of environment information in a real environment. An environment information database 140 is connected with the environment information collecting system 120, and an electronic chart information in the real environment and the at least one piece of environment information in the real environment are stored in the environment information database 140. An environment model building module 160 is connected with the environment information collecting system 120 and the environment information database 140, and the environment model building module 160 is configured to integrate the at least one piece of environment information with the electronic chart information, building at least one environment model. In other possible embodiments, the environment model building system 100 can build multiple environment models and merge them to form a large-scale environment model such as a nautical model.

The environment information collecting system 120 is a camera or a laser scanning device, using unmanned aerial vehicle (UAV) to take front or side shots and high-precision laser methods to obtain real-world object information, including the object containing relatively obvious outline, such as shoreline information, port information, and large-scale building information, to facilitate the subsequent large-scale 3D reverse modeling of the real environment. In addition, if there is a blind spot of the camera, the laser scanning device is used to obtain the absolute coordinates of the object model in a complex environment, such as bridge piers and offshore wind turbines and other smaller structural objects. Otherwise, in order to get more information from the real environment, the environmental information collection module 120 is alternatively an anemometer or a sensor that monitors the waves and ocean currents (tidal currents) to obtain climate information including monsoon, fog, or thunderstorms, and water surface information such as waves or ocean currents (tidal currents).

The environment information database 140 not only stores the aforementioned water surface information, climate information, and object information of the real environment, but also has built-in electronic chart information of the real environment, so that the environment information building module 160 can be used to build a three-dimensional environmental model of the real environment based on the electronic chart integrating with the aforementioned environment information.

Specifically, the environment information building module 160 builds a three-dimensional environment model of the real environment as following. First, use the electronic chart information of the real environment as the base, and use GIS and 3Ds Max to perform post-production to obtain the contour information of the coastline or river channel; in addition, the irregular grid model can also be used to create the seabed and riverbed Digital Elevation Model (DEM), completing the integration of seabed and riverbed DEM with land DEM. Next, use the object information obtained by the camera or laser scanning device to restore the real and lifelike terrain, landmarks and buildings. The preceding method uses unmanned aerial vehicle (UAV) to perform large-scale three-dimensional reverse modeling to obtain three-dimensional images of the real environment and optimize it with computer topology computing technology.

Furthermore, establish a water surface model and a water current numerical simulation model (collectively referred to as water surface information), and represent water surface real time water level with fix term and disturbance term two parts. The fix term is depth datum, and the disturbance term comprises ocean currents and tidal currents. Simultaneously, adopt the astronomical tide numerical forecast model based on the assimilation of tide table data for tide forecast to obtain depth information of the instantaneous water surface. The water current numerical simulation model based on the CAD drawing of the channel measures flow, water level and gradient information, establishes the mass conservation continuum equation and the momentum conservation motion equation, and conducts the numerical simulation of the flow field. Finally, simulation calculation results of the aforementioned electronic chart information, object information, and water surface information are associated and integrated, and various data are comprehensively displayed to construct a virtual reality three-dimensional scene; in addition, different Scene mode can be switched according to weather information, including scenes such as heavy fog or thunderstorm.

In the embodiment, the purpose of the vessel model building system 200 is to build a vessel model to provide a virtual ship for navigation testing. The vessel model building system 200 comprises: a vessel parameter setting module 220, setting at least one dynamic parameter and at least one static parameter of the at least one vessel. A vessel information database 240 is connected with the vessel parameter setting module 220, and the at least one dynamic parameter and the at least one static parameter are stored in the vessel information database 240. A vessel model building module 260 is connected with the vessel parameter setting module 220 and the vessel information database 240, and the vessel model building module 260 is configured to integrate the at least one dynamic parameter with the at least one static parameter in order to build the at least one vessel model.

Specifically, the dynamic parameter comprises (initial) position of the at least one vessel, (initial) vessel speed, (initial) propeller speed, (initial) rudder angle, et cetera. Anything that will change over time after the parameter is set is within the protection scope of the present invention. On the other hand, the static parameter comprises vessel type, length of vessel, weight of vessel, biggest draft, biggest ship speed, biggest rotational speed, biggest rudder angle or the combination thereof. Any parameter that is fixed after its value is set falls within the protection scope of the present invention. The vessel information database 240 can store the aforementioned dynamic parameters and the static parameters, and the vessel model building module 260 can build a new virtual ship model through the dynamic parameters and the static parameters updated by the user. The data in the vessel information database 240 could be accessed to use historical virtual ship models.

In the embodiment, the central processing system 300 connects with the environment model building system 100 and the vessel model building system 200 to integrate the vessel model into the environment model and perform simulation in a virtual field based on the navigational parameters provided by the user. The central processing system 300 comprises: a navigational parameter setting module 320 sets at least one navigational parameter. An operation module 340 is connected with the navigational parameter setting module. The operation module is configured to integrate the environment model with the vessel model to allow the vessel model to be navigated through the environment model according to the at least one navigational parameter. Furthermore, a display module 360 is connected with the operation module 340, and the environment model and the vessel model are displayed on the display module 360.

Specifically, the navigational parameter comprises departure point and destination point, route, obstacle site, or tracking target, et cetera (please refer to table 1). The operation module 340 connects with the navigational parameter setting module 320. The operation module 340 is configured to integrate the environment model with the vessel model to allow the vessel model to be navigated through the environment model according to the at least one navigational parameter. For example, after the user sets the departure point and destination point of sailing and the tracking target, the vessel model will be in the environment model, starting from the departure point and following the track of the tracking target until arriving the destination point. If obstacle parameters are set during the voyage, the vessel model will automatically avoid obstacles during navigation, or detect objects in front to avoid collisions automatically to complete the simulation of autonomous vessels. In view of this, the operation module 340 of the present invention further includes obstacle avoidance algorithms, collision avoidance algorithms and path tracking algorithms, and detailed implementation of obstacle avoidance algorithms, collision avoidance algorithms and path tracking algorithms will be further described in the following paragraphs. In addition, multiple vessel models can be simulated simultaneously under the same environment model.

TABLE 1
Environment information, vessel parameter and navigational
parameter of the embodiment.

| title | Set items | | explanation |
|---|---|---|---|
| Environment | field | | Select the simulation of field, such |
| information | | | as Kaohsiung Port, Taichung |
| | | | Port, Taipei Port, |
| | | | et cetera. |
| | Wind speed | | Simulate the wind speed |
| | Wind direction | | Simulate the wind direction |
| | Water velocity | | Simulate the water velocity |
| | (knot) | | |
| | Set (degree) | | Simulate the set |
| | Sea state (scale) | | Simulate the sea state |
| Vessel | vessel type | | Select the simulation of vessel |
| parameters | | | type, such as |
| | | | solar-powered boat 3, 5 meter |
| | | | boat, yacht, etc. |
| | Vessel speed | | The expected vessel speed of the |
| | (knot) | | autonomous navigation |
| | propeller | KP | The parameter P controlled by |
| | | | propeller speed PID |
| | | KI | The parameter I controlled by |
| | | | propeller speed PID |
| | | KD | The parameter D controlled |
| | | | by propeller speed PID |
| | | Direct | Transfer the left engine |
| | | propeller | order, the middle |
| | | speed | engine order and the |
| | | control | right engine order of |
| | | | changing the speed |
| | | | according to the vessel |
| | | | type |
| | rudder | KP | The parameter P controlled by |
| | angle | | rudder angle PID |
| | | KI | The parameter I controlled by |
| | | | rudder angle PID |
| | | KD | The parameter D controlled by |
| | | | rudder angle PID |
| | | Direct | Transfer the rudder angle |
| | | rudder | order according to |
| | | angle | the vessel type |
| | | control | |
| navigational | Tracking | distance | Where the distance of the |
| parameters | point | from the | tracking point from |
| | | vessel | the vessel is smaller than |
| | | (meter) | the specified value, |
| | | | the guidance |
| | | | point moves forward |
| | | The | The distance that the |
| | | advance | tracking point moves |
| | | distance | each time |
| | | (meter) | |
| | collision | collision | Where the distance of the |
| | avoidance | avoidance | obstacles from the |
| | control | distance | vessel is smaller than |
| | | (meter) | the specified value, |
| | | | perform the |
| | | | collision avoidance |
| | | obstacle | Where calculating the |
| | | avoidance | guidance point of |
| | | distance | collision avoidance, the |
| | | (meter) | distance between the |
| | | | guidance point and the obstacles |

First of all, in the embodiment, the first method of using obstacle avoidance algorithms, collision avoidance algorithms and path tracking algorithms comprises the following steps: (a) navigate the vessel model along a route setting by the user (navigational parameters). The route comprising at least two nodes, and the at least two nodes comprising a first node and a second node (the number of nodes can be set according to the navigation path, and present invention should not be limited by the abovementioned), and a first line segment connects the first node with the second node; (b) where the vessel model is navigated to a distance from the first node or an original tracking point smaller than a first length, a first tracking point situated on the first line segment is produced, and the vessel model is navigated according to the first tracking point. The first tracking point has a distance of a second length from the first node; (c) where the vessel model is navigated to a distance from the first tracking point smaller than the first length, a second tracking point situated on the first line segment is produced, and the vessel model is navigated according to the second tracking point. The second tracking point has a distance of the second length from the first tracking point; (d) repeating steps (b)-(c) until the vessel completing the navigation through every node.

In a further step (a1) added after step (a), the vessel model is navigated along the first line segment, then deviating from the original route as a result of an external factor interfering, ending in step (b). The external factor may be the environment information including wind power, waves, ocean current or the combination thereof set by the users. Otherwise, during the navigation of the preset route, the external factor may be an accident detected on the path, such as other ship models sailing to the preset route, or the presence of reefs or large marine life in the navigation path, etc., causing the vessel model deviating from the original navigation path due to avoiding obstacles or avoiding collisions during navigation.

Next, in the other embodiment, the second method of using obstacle avoidance algorithms, collision avoidance algorithms and path tracking algorithms comprises the following steps: (g) navigate the vessel model along a route, and the route comprising at least two nodes. The at least two nodes comprise a first node and a second node and a third node. A first line segment connects the first node with the second node and a second line segment connects the second node with the third node (the number of nodes can be set according to the navigation path, and present invention should not be limited by the abovementioned), and a first line segment connects the first node with the second node and a second line segment connects the second node with the third node; (h) where the vessel model is navigated to a distance from the first node or an original tracking point smaller than a first length, a first tracking point situated on the first line segment is produced, and the vessel model is navigated according to the first tracking point, the first tracking point has a distance of a second length from the first node; (i) where the vessel model is navigated to a distance from the first tracking point smaller than the first length and the distance between the first tracking point and the second node is smaller than the second length. A second tracking point situated on the second line segment is produced, and the vessel model is navigated according to the second tracking point, and the second tracking point has a distance of the second length from the first tracking point; and (j) repeating steps (h)-(i) until the vessel completing the navigation through every node. The difference between the first method and the second method mentioned above lies in that since the distance from the original tracking point to the next node is less than the second length, the new tracking point must be located on the next line segment (connection link between the nodes) considering the original line segment (connection link between the nodes), leading to the route across the nodes. It is worth noting that when the vessel model is navigated following the tracking point under the condition that a set obstacle is detected on its path, the obstacle should be first avoided before continuing to be navigated through the tracking point.

In a further step (g1) added after step (g), the vessel model is navigated along the first line segment, then deviating from the original route as a result of an external factor interfering, ending in step (h). The external factor may be the environment information including wind power, waves, ocean current or the combination thereof set by the users. Otherwise, during the navigation of the preset route, the external factor may be an accident detected on the path, such as other ship models sailing to the preset route, or the presence of reefs or large marine life in the navigation path, etc., causing the vessel model deviating from the original navigation path due to avoiding obstacles or avoiding collisions during navigation.

The preceding vessel model, environment model, and the scene of the vessel model navigated through the environment model can be displayed through the display module 360. Specifically, the display module 360 is a VR or AR display module, which can show the real world more vividly. In addition, the display module 360 can also display the environment information, vessel parameters, and navigational parameters on the screen simultaneously, so that the user knows the data of the environment model and the operating status of the vessel model. As such, the present invention conducts simulation experiments through model ships, which can provide experimental data for the operation and control of the autonomous ships, and ultimately ensure safety of the navigation of inland/ocean ships. The system reduces the difficulty and cost of ship experiments.

It is noteworthy that the central processing system 300 of the present embodiment of the autonomous vessel simulation system 10 further comprises a control module 380, connected with the operation module 340 and the display module 360. In other words, the present invention is available in multiple modes at the same time, including “experimental test mode”, “control test mode” and “remote control mode”. In the “experimental test mode”, the user can set at least one navigational parameter in the built environment model and vessel model, so that the vessel model can be navigated in the environment model field according to the set value of the navigational parameter; in the “control test mode”, the same user can use the built environment model and vessel model to control independently the navigation status of the vessel model in the environment model through a control module 380 connected to the operation module 340 and the display module 360, and the navigation status is demonstrated on the display module 360; finally, in the “remote control mode”, a physical ship is placed in the real environment first, and then the environment model of the real environment and the vessel model of the physical ship are built. Meanwhile, the environment model may be the images taken by the camera or other optical sensors on the physical ship. The user can use the control module 380 connected to the operation module 340 and the display module 360 to remotely control the navigation status of the physical ship, displaying the scene of the navigation status on the display module 360.

It is noteworthy that the autonomous vessel simulation system 10 of the present embodiment further comprises an external processing system 400, connected with the central processing system 300. The external processing system 400 comprises: an external navigational parameter setting module 420, setting the at least one navigational parameter of the at least one vessel model. An external display module 460 is connected with the operation module 340, and the environment model and the vessel model are displayed on the external display module 460. Through the external navigational parameter setting module 420 of the external processing system 400, the user can remotely input navigational parameters such as departure point and destination point, route, obstacle positions, or tracking targets, and integrate the environment model, the vessel model, and the external navigation parameters by the central processing system 300, the navigation screen of the vessel model in the environment model is transmitted to the external display module 460; in other words, the user can remotely execute the simulation system 10 of this embodiment. It is worth noting that if the format of the external navigational parameters input by the external user is incorrect, the central processing system 300 will send an error message and indicate the wrong parameter to facilitate the user to make format corrections.

The effect of the present invention is that: first, for the self-driving function, multiple control parameters can be adjusted, or directly input the propeller speed, rudder angle, navigation destination point, etc. into the system from the outside through the network data transmission; the user is allowed to choose the function, the built-in program and the function to input according to the test items; next, this simulation system includes a virtual reality built based on the real field. Not only can the scene reflect the posture and movement of the ship's six degrees of freedom in real time, the user can also directly see the selected field on the screen. The surrounding environment simulates the actual navigation situation, immediately observes the control effect and adjusts the parameters thereafter. Third, with this simulation system, the self-driving boat development team can conduct simulation tests in the laboratory to comprehensively consider and adjust all possible situations and self-driving control parameters before the real field test stage, saving the cost of directly entering the real field of trial and error, and increasing the safety of testing.

The ordinal numbers used in the detailed description and claims, such as “first” and “second” do not necessarily indicate their priority orders or up and down directions; on the contrary, they are merely intended to distinguish different elements. It will be apparent to those skilled in the art that various modifications and variations can be made to the structure of the present invention without departing from the scope or spirit of the invention. In view of the foregoing, it is intended that the present invention covers modifications and variations of this invention, provided they fall within the scope of the following claims.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. While the preferred embodiment of the invention has been illustrated and described, it will be appreciated that various changes can be made therein without departing from the spirit and scope of the invention.

What is claimed is:

1. An autonomous vessel simulation system, comprising:
an environment model building system, building at least one environment model, the environment model building system comprising:
an environment information collecting system, collecting at least one piece of environment information in a real environment;
an environment information database, connected with the environment information collecting system, wherein electronic chart information in the real environment and the at least one piece of environment information in the real environment are stored in the environment information database; and
an environment model building module, connected with the environment information collecting system and the environment information database, wherein the environment model building module is configured to integrate the at least one piece of environment information with the electronic chart information, building at least one environment model;
a vessel model building system, building at least one vessel model, wherein the vessel model building system comprising:
a vessel parameter setting module, wherein at least one dynamic parameter and at least one static parameter of the at least one vessel are set by the vessel parameter setting module;
a vessel information database, connected with the vessel parameter setting module, wherein the at least one dynamic parameter and the at least one static parameter are stored in the vessel information database; and
a vessel model building module, connected with the vessel parameter setting module and the vessel information database, wherein the vessel model building module is configured to integrate the at least one dynamic parameter with the at
least one static parameter, building the at least one vessel model; and
a central processing system, connected with the environment model building system and the vessel model building system, wherein the central processing system comprising:
a navigational parameter setting module, setting at least one navigational parameter;
an operation module, connected with the navigational parameter setting module, wherein the operation module is configured to integrate the at least one environment model with the at least one vessel model, allowing the at least one vessel model to be navigated through the at least one environment model with the at least one navigational parameter; and
a display module, connected with the operation module, wherein the at least one environment model and the at least one vessel model are displayed on the display module.

2. The autonomous vessel simulation system as claimed in claim 1, further comprising at least one external processing system, connected with the central processing system.

3. The autonomous vessel simulation system as claimed in claim 2, wherein the external processing system comprising:
an external navigational parameter setting module, setting the at least one navigational parameter of the at least one vessel model; and
an external display module, connected with the operation module, wherein the at least one environment model and the at least one vessel model are displayed on the external display module.

4. The autonomous vessel simulation system as claimed in claim 1, wherein the environment information collecting system comprising a camera or a laser scanning device.

5. The autonomous vessel simulation system as claimed in claim 1, wherein the at least one piece of environment information comprising object information, water surface information, climate information or the combination thereof.

6. The autonomous vessel simulation system as claimed in claim 1, wherein the at least one dynamic parameter comprising position of the at least one vessel, vessel speed, propeller speed, rudder angle or the combination thereof.

7. The autonomous vessel simulation system as claimed in claim 1, wherein the at least one static parameter comprising vessel type, length of vessel, weight of vessel, draft or the combination thereof.

8. The autonomous vessel simulation system as claimed in claim 1, wherein the at least one navigational parameter comprising departure point and destination point, route, obstacle site, tracking target or the combination thereof.

9. The autonomous vessel simulation system as claimed in claim 1, wherein the operation module comprising an obstacle avoidance algorithm, a collision avoidance algorithm or a path tracking algorithm.

10. The autonomous vessel simulation system as claimed in claim 1, wherein the central processing system further comprising a control module, connected with the operation module and the display module.

11. A method of using an autonomous vessel simulation system, wherein the steps comprise:
(A) Provide an autonomous vessel simulation system as claimed in claim 1;
(B) An environment model building system builds at least one environment model;
(C) A vessel model building system builds at least one vessel model;
(D)An operation module of a central processing system integrates the at least one environment model with the at least one vessel model;
(E) A display module shows the at least one environment model and the at least one vessel model; and
(F) The operation module allows the at least one vessel model to be navigated through the at least one environment model using the at least one navigational parameter set by a navigational parameter setting module.

12. The method of using the autonomous vessel simulation system as claimed in claim 11, wherein, in step (B), the environment model building system integrates at least one piece of environment information with electronic chart information, building the at least one environment model.

13. The method of using the autonomous vessel simulation system as claimed in claim 11, wherein, in step (C), the vessel model building system integrates at least one dynamic parameter with at least one static parameter of at least one vessel, building the at least one vessel model.

14. The method of using the autonomous vessel simulation system as claimed in claim 11, wherein, in step (F), the operation module further allows the at least one vessel model to be navigated through the at least one environment model using at least one external navigational parameter set by an external navigational parameter setting module.

15. The method of using the autonomous vessel simulation system as claimed in claim 14, wherein, in step (F), the at least one navigational parameter and the at least one external navigational parameter comprising departure point and destination point, route, obstacle site, tracking target or the combination thereof.

16. The method of using the autonomous vessel simulation system as claimed in claim 11, wherein, after step (E), a control module is used in an alternative step (f) to allow the at least one vessel model to be navigated through the at least one environment model.

17. The method of using the autonomous vessel simulation system as claimed in claim 11, wherein the operation module comprises an obstacle avoidance algorithm, a collision avoidance algorithm or a path tracking algorithm.

18. The method of using the autonomous vessel simulation system as claimed in claim 17, wherein the steps of implementing the operation module comprising:
(a) navigate the at least one vessel model along a route, wherein the route comprising at least two nodes, and wherein the at least two nodes comprising a first node and a second node, and wherein a first line segment connects the first node with the second node;
(b) where the at least one vessel model is navigated to a distance from the first node smaller than a first length, a first tracking point situated on the first line segment is produced, and the at least one vessel model is navigated according to the first tracking point, wherein the first tracking point has a distance of a second length from the first node;
(c) where the at least one vessel model is navigated to a distance from the first tracking point smaller than the first length, a second tracking point situated on the first line segment is produced, and the at least one vessel model is navigated according to the second tracking point, wherein the second tracking point has a distance of the second length from the first tracking point;
(d) repeating steps (b)-(c) until the at least one vessel completing the navigation through every node.

19. The method of using the autonomous vessel simulation system as claimed in claim 17, wherein the steps of implementing the operation module comprising:
(g) navigate the at least one vessel model along a route, wherein the route comprising at least two nodes, and wherein the at least two nodes comprising a first node, a second node and a third node, and wherein a first line segment connects the first node with the second node and a second line segment connects the second node with the third node;
(h) where the at least one vessel model is navigated to a distance from the first node smaller than a first length, a first tracking point situated on the first line segment is produced, and the at least one vessel model is navigated according to the first tracking point, wherein the first tracking point has a distance of a second length from the first node;
(i) where the at least one vessel model is navigated to a distance from the first tracking point smaller than the first length and the distance between the first tracking point and the second node is smaller than the second length, a second tracking point situated on the second line segment is produced, and the at least one vessel model is navigated according to the second tracking point, wherein the second tracking point has a distance of the second length from the first tracking point; and
(j) repeating steps (h)-(i) until the at least one vessel completing the navigation through every node.
